(19) United States
(12) Patent Application Publication
(10) Pub. No.: US 2026/0239535 A1
(43) Pub. Date: Aug. 13, 2026

(54) Component Carrier and Method of Manufacturing the Same

(71) Applicant: AT&S Austria Technologie & Systemtechnik Aktiengesellschaft, Leoben (AT)

(72) Inventor: Jeesoo MOK, Leoben (AT)

(21) Appl. No.: 19/155,246

(22) PCT Filed: Sep. 28, 2023
(86) PCT No.: PCT/EP2023/076856

§ 371 Date: Aug. 9, 2025

(30) Foreign Application Priority Data
Feb. 9, 2023 (CN) 202310100045.5

(51) Int. Cl. H05K 1/11; H05K 1/02; H05K 1/03; H05K 1/181; H05K 3/00; H05K 3/42; H05K 3/46

(52) U.S. Cl. CPC H05K 1/115; H05K 1/0243; H05K 1/0306; H05K 1/0313; H05K 1/181; H05K 3/0094; H05K 3/42; H05K 3/4605; H05K 2201/09563; H05K 2201/09827; H05K 2203/107

(57) ABSTRACT

A component carrier and a method of manufacturing the same are disclosed. The component carrier includes a carrier body having at least one hole, electrically conductive paste in at least part of the at least one hole, and at least one conductive interconnection structure extending with direct physical contact into the electrically conductive paste.

### CROSS REFERENCE TO RELATED APPLICATIONS

This application is a national stage application, filed under 35 U.S.C. § 371, of International Patent Application No. PCT/EP2023/076856, filed on Sep. 28, 2023, claiming priority of the filing date of the Patent Application No. 202310100045.5, filed on Feb. 9, 2023, with the China National Intellectual Property Administration, the disclosures of which are hereby incorporated by reference herein in their entirety.

### TECHNICAL FIELD

The disclosure relates to a component carrier, and to a method of manufacturing a component carrier.

### TECHNICAL BACKGROUND

In the context of growing product functionalities of component carriers equipped with one or more components and increasing miniaturization of such components as well as a rising number of components to be connected to the component carriers such as printed circuit boards or component carriers, increasingly more powerful array-like components or packages having several components are being employed, which have a plurality of contacts or connections, with smaller and smaller spacing between these contacts. In particular, component carriers shall be mechanically robust and electrically reliable so as to be operable even under harsh conditions.

Conventional approaches of forming component carriers are still challenging.

### SUMMARY

There may be a need to form a compact and reliable component carrier-type package.

This need is met by the subject matter according to the independent claims. Further embodiments are described by the dependent claims.

According to an example embodiment of the disclosure, a component carrier is provided which comprises a carrier body having at least one hole, electrically conductive paste in at least part of the at least one hole, and at least one conductive interconnection structure extending with direct physical contact into the electrically conductive paste.

According to another example embodiment of the disclosure, a method of manufacturing a component carrier is provided, wherein the method comprises providing a carrier body with at least one hole, inserting electrically conductive paste into at least part of the at least one hole, and forming at least one conductive interconnection structure extending with direct physical contact into the electrically conductive paste.

### Overview of Embodiments

In the context of the present application, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic or inorganic interposer, and an IC (integrated circuit) substrate. A component carrier may also be a hybrid board combining different ones of the above-mentioned and/or other types of component carriers.

In the context of the present application, the term “carrier body” may particularly denote a physical structure (for instance a plate-type structure) providing mechanical stability for carrying constituents of the component carrier. For instance, the carrier body may be a base structure being processed during a manufacturing process of the component carrier for forming constituents of the component carrier thereon and therein. On the other hand, the carrier body can also comprise a core with the option of multiple layers and/or signal layers comprising at least one electrically insulating layer and electrically conductive layer which can provide the function of electrical transmission and/or thermal dissipation.

In the context of the present application, the term “hole of carrier body” may particularly denote an opening or via in the carrier body. Such a hole may be a through hole extending through the entire carrier body, may be a blind hole extending into the carrier body but having a closed bottom, or may be a groove, cavity (for instance for embedding a component) or recess of any shape. While executing a method of filling holes of a carrier body with an electrically conductive paste according to an example embodiment, it may be possible that at least 10 holes, in particular at least 100 holes of the carrier body are filled partially or entirely with electrically conductive paste.

In the context of the present application, the term “electrically conductive paste” may particularly denote a paste or paint or glue or ink with (preferably high) electrical and/or thermal conductivity comprising an electrically conductive material such as a metallic material and/or an adhesive material with good adhesion. It may also comprise solvent for improving the electrical and mechanical performance of the conductive paste. A paste may be a substance that behaves as a solid until a sufficiently large load or stress or temperature is applied, at which point it flows like a fluid. Such a paste may comprise a suspension of granular material in a fluid matrix. For instance, the electrically conductive paste may be a metallic paste or a magnetic paste. In particular, the electrically conductive paste may be a sinter paste.

In the context of the present application, the term “conductive interconnection structure” may particularly denote a physical structure made of an electrically conductive and/or thermally conductive material and being configured for providing an electric and/or a thermal connection function in the component carrier. For example, the conductive interconnection structure may be a metallic material (for example copper) or another material with electrical and/or thermal conductivity (for instance graphite). In particular, the conductive interconnection structure may be a solid material, such as a solid metallic material. For instance, the conductive interconnection structure may be configured as a metallic via (in particular a tapering metallic via or a metallic laser via), a pillar, a bump, etc. The conductive interconnection structure may have a tapering or straight end section. In particular, a conductive interconnection structure may extend vertically into the carrier body. A plurality of conductive interconnection structures may extend into different holes of the carrier body, for instance parallel to each other.

In the context of the present application, the term “direct physical contact” may particularly denote a face-to-face contact between two connected entities contacting each other without an additional intermediate material in between. Such a direct physical contact may also establish a direct physical connection between the connected entities. In particular, direct physical contact between the conductive interconnection structure and the electrically conductive paste may create a proper electric and/or thermal connection between the conductive interconnection structure and the electrically conductive paste.

In the context of the present application, the term “main surface” of a body may particularly denote one of two largest opposing surfaces of the body or two outermost surfaces of the body. The main surfaces may be connected by circumferential side walls. The thickness of a body, such as the carrier body, may be defined by the distance between the two opposing main surfaces.

According to an example embodiment of the disclosure, a component carrier is equipped with a carrier body having one or more holes extending therein. An electrically conductive paste may be inserted in the one or more holes to fill them partially or entirely. Advantageously, a conductive interconnection structure may be inserted with direct physical contact into the electrically conductive paste, to thereby establish a reliable electric and/or thermal connection between an interconnection structure and paste. By the described manufacturing architecture, it may be possible to form in a simple and reliable way an electric and/or thermal connection to the electrically conductive paste filling a hole of a carrier body. Advantageously, such a connection can be created in a quick and easy way on an industrial scale, with a high yield and for very different applications.

When forming the conductive interconnection structure by laser drilling (or etching, in particular plasma etching) into the electrically conductive paste followed by subsequent metal plating, the provision of a paste may be of utmost advantage, since this will not lead to excessive laser light reflection as it may happen with a solid bulk metal. Hence, the component carrier may be protected against overheating during laser drilling and against formation of artefacts. Consequently, a reliable component carrier may be obtained.

### Example Embodiments

In the following, further example embodiments of the component carrier and the method will be explained.

In an embodiment, the at least one hole is at least one hole extending through the entire carrier body. Forming one or more through holes in the carrier body and filling them with electrically conductive paste may allow contact of the electrically conductive paste at both opposing ends of the hole by two conductive interconnection structures. Hence, also a two-sided connection may be formed with low effort and high reliability.

In an embodiment, the carrier body is an inorganic carrier body, in particular comprising or consisting of glass, ceramic, or a semiconductor, for example silicon. In the context of the present application, the term “inorganic carrier body” may particularly denote a carrier structure which comprises inorganic material. As an example, a suitable inorganic material may be an inorganic compound. In particular, dielectric material of the inorganic carrier body or even the entire inorganic carrier body may be made exclusively or at least substantially exclusively from inorganic material. In another embodiment, the inorganic carrier body may comprise inorganic dielectric material and additionally another dielectric material and/or other inorganic material. An inorganic compound may be a chemical compound that lacks carbon-hydrogen bonds or a chemical compound that is not an organic compound. In an example, the inorganic carrier body may comprise glass, for example silicon base glass, in particular soda lime glass, and/or boro-silicate glass and/or alumo-silicate glass and/or lithium silicate glass and/or alkaline free glass. In another example, the inorganic carrier body may comprise ceramic material, for example aluminum nitride and/or aluminum oxide and/or silicon nitride and/or boron nitride and/or tungsten comprising ceramic material. Yet, in another example, the inorganic carrier body may comprise semi-conductive material, for example silicon and/or germanium and/or silicon oxide and/or germanium oxide and/or silicon carbide and/or gallium nitride. In a further embodiment, the inorganic carrier body may comprise elemental metal and/or metal alloys, for example, copper and/or tin and/or bronze. Yet in another embodiment, the inorganic carrier body may comprise inorganic material, which is not listed in the above-mentioned examples, such as: MoS₂, CuGaO₂, AgAlO₂, LiGaTe₂, AgInSe₂, CuFeS₂, BeO.

Most preferred is a carrier body comprising glass or consisting of glass. Such a carrier body may comprise or consist of silicon dioxide. In particular, the glass carrier body may have glass as the main constituent. For example, the glass carrier body may be block-, strip- or plate-shaped. The major material component (in particular the material component of the glass carrier body providing the highest weight percentage) of the glass carrier body is glass, in particular silicon-based glass. For instance, at least 90 weight percent of the glass carrier body may be glass. For example, the glass carrier body may consist only of glass. It is, however, also possible that the glass carrier body comprises one or more additional other materials. Advantageously, the glass carrier body may have very flat surfaces so that a planarization stage during processing may be dispensable and fine line processing thereon or above it may be fully supported. Furthermore, the glass carrier body may have a high degree of thermal stability so that thermally caused undesired phenomena such as thermal stress, shrinkage, warpage and delamination will not impact the component carrier significantly. This can make the whole component carrier stable with controllable change of the dimension of the component carrier (such as shrinkage would be less), so the alignment of all elements related to the component carrier and/or the whole package may be improved (such as layer to layer alignment, via to pad alignment, pad to via alignment, bump to opening alignment, etc.). Besides that, the coplanarity of components assembled on the component carrier may be improved (such as bumps, capacitors, etc.). Furthermore, glass material may show a low DK and low DF behavior with good dielectric property and may therefore support low loss, high-frequency (in particular improving radio-frequency, RF) and high-speed applications as well as high performance computing application with good signal integrity and low loss.

In an embodiment, a surface roughness Ra of the carrier body, in particular when embodied as glass body, is not more than 100 nm, in particular not more than 50 nm. Such a low roughness Ra may ensure that a patterned metal layer may be formed on or above this surface of the glass carrier body with highest spatial accuracy. Thus, the described embodiment may be particularly appropriate for high density integration (HDI) applications and/or for fine line patterning.

In an embodiment, the carrier body is an organic carrier body, in particular comprising or consisting of a resin. In the context of the present application, the term “organic carrier body” may particularly denote a block-, strip- or plate-shaped structure which comprises a dielectric material having an organic compound. In particular, dielectric material of the organic carrier body may be made exclusively or at least substantially exclusively from organic material. In another embodiment, the organic carrier body may comprise organic dielectric material and/or additionally another dielectric material. An organic compound may be a chemical compound that contains carbon-hydrogen bonds. For example, the organic carrier body may comprise an organic resin material, an epoxy material, etc. For instance, the organic carrier body may be an organic integrated circuit (IC) substrate or a printed circuit board (PCB). In particular, integrated circuit substrates dielectrics may be dielectrics used for the organic integrated circuit substrate.

In an embodiment, at least two conductive interconnection structures are provided, each one extending with direct physical contact into said electrically conductive paste from a respective one of two opposing ends of the at least one hole extending through the entire carrier body. Hence, each of the two opposing and exposed end portions of the electrically conductive paste next to the opposing main surfaces of the for instance plate-shaped carrier body may be contacted thermally and/or electrically by a respective conductive interconnection structure protruding therein. Thus, a symmetric contact structure may be formed on both sides of the carrier body which may limit warpage.

In an embodiment, the component carrier comprises a dielectric layer directly on a main surface of the carrier body, wherein the conductive interconnection structure extends through the dielectric layer. Such a dielectric layer which may be formed directly on a main surface of the carrier body may space the carrier body with respect to fine line patterns which may be formed on the dielectric layer. It has turned out that such a dielectric layer simplifies processing of electrically connected fine line patterns which may adhere better to the dielectric layer than directly to the carrier body, in particular when made of glass. Thus, a sandwiched dielectric layer may improve the reliability of the obtained component carrier, since it makes it easier to control warpage and improve handling of such products during manufacturing and of a final product.

In an embodiment, the component carrier comprises a further dielectric layer directly on an opposing other main surface of the carrier body, wherein a further conductive interconnection structure extends through the further dielectric layer into the electrically conductive paste. In order to increase the degree of symmetry of build-ups on both opposing main surfaces of the carrier body, a respective dielectric layer may be attached directly on each of the two opposing main surfaces of the carrier body. In particular, this may further reduce warpage and may enhance adhesion of a metallic pattern which may be formed on the dielectric layer surfaces facing away from the carrier body.

In an embodiment, the dielectric layer has a smaller thickness than a thickness of the further dielectric layer. The overall layer build-up on both opposing sides of the carrier body may be generally asymmetric. This may be due to the fact that a mounting base, such as a printed circuit board with large pitch, may be mounted on one side of the component carrier, whereas an electronic component, such as a semiconductor chip with smaller pitch, may be mounted on the opposing other side of the carrier (see FIG. 7). Such an asymmetric build-up with different integration density of electrically conductive structures on both opposing sides of the carrier body may be a root cause of warpage. When forming the dielectric layer on the side of the carrier body with thinner build-up thicker than on the side of the carrier body with a thicker build-up, the asymmetry of the build-ups can be at least partially compensated by the dielectric layers of unequal thicknesses. This may lead to reduced warpage and a better reliability of the component carrier. Moreover, this configuration can also have cost benefits, since it may differentiate the layer counts of two opposite sides based on an actual application.

For instance, a thickness of the dielectric layer may be in a range from 5 μm to 20 μm, for example 10 μm. Such a small thickness may allow a fine line pattern on the dielectric layer to benefit from the high smoothness of the carrier body directly beneath the thin dielectric layer. For example, a thickness of the further dielectric layer may be in a range from 50 μm to 200 μm, for instance 100 μm. Such different dimensions of the dielectric layers may allow for an at least partial compensation of thickness differences of build-ups on both opposing sides of the carrier body.

In an embodiment, the component carrier comprises a redistribution structure formed on or above a main surface of the carrier body, in particular formed only on or above one of two opposing main surfaces of the carrier body. For example, the redistribution structure may be a redistribution layer (RDL). In the context of the present application, the term “redistribution structure” may particularly denote a plurality of patterned electrically conductive layer structures in a dielectric matrix which have a portion with a smaller pitch as compared to another portion with a larger pitch. Pitch may denote a characteristic distance between adjacent electrically conductive structures, such as wiring elements or terminals or pads, for instance a center-to-center distance between adjacent electrically conductive structures. By providing spatially separate regions with different pitch, a redistribution structure may be an electric interface between larger dimensioned electric connection structures (in particular relating to printed circuit board technology) and smaller dimensioned electric connection structures (in particular relating to semiconductor chip technology, wherein a connectable component may be a semiconductor chip). In particular, a number of electrically conductive structures per area or volume may be larger in a region with smaller pitch than in another region with larger pitch. A region with larger pitch may be arranged where the glass carrier body is located, whereas another region with smaller pitch may be arranged at a periphery or an outer region of the component carrier where an electronic component is to be electrically connected. No redistribution structure needs to be present on the opposing other side of the glass carrier body having a build-up to be connected to a mounting base, such as a printed circuit board.

In an embodiment, the at least one conductive interconnection structure passes through at least part of the redistribution structure or forms part thereof. Hence, electric signals to be redistributed may also be guided through the respective conductive interconnection structure.

In an embodiment, the redistribution structure is formed on the dielectric layer or is formed so that the dielectric layer forms part of the redistribution structure. Thus, the dielectric layer may functionally contribute not only to an improved adhesion of a fine line pattern on this dielectric layer (rather than directly on the glass carrier body) but may fulfill the additional function of forming part of a redistribution structure. This double function may lead to an efficient manufacturing process and a compact design of the component carrier.

In an embodiment, a build-up on two opposing main surfaces of the carrier body is asymmetric. For example, the build-up on one side of the carrier body may comprise the above-mentioned redistribution structure. The asymmetric configuration of the build-up on the two opposing main surfaces of the carrier body may include different thicknesses, different pitches or integration density, and/or different material composition of the build-ups. Although an asymmetric build-up may involve the risk of warpage, the presence of a carrier body which is preferably made of glass in between may significantly reduce the tendency of warpage due to the pronounced rigidity of glass. Furthermore, one or more further countermeasures may be taken against warpage, such as a thinner dielectric layer directly on the carrier body on the side with the thicker build-up as compared to a thicker dielectric layer directly on the opposing side of the carrier body with the thinner or no build-up.

More specifically, the component carrier may comprise a top-sided layer build-up vertically between the carrier body on the one hand and a surface mounted electronic component on the other hand. The layer build-up may be embodied in form of a laminated layer stack. Such a laminated layer stack may be formed of one or more electrically insulating layer structures (such as prepreg sheets) and one or more electrically conductive layer structures (such as copper vias and/or patterned copper foils or layers). In the context of the present application, the term “stack” may particularly denote an arrangement of multiple planar layer structures which are mounted in parallel on top of one another. Furthermore, the term “layer structure” may particularly denote a continuous layer, a patterned layer or a plurality of non-consecutive islands within a common plane. The carrier body, in particular when embodied as glass carrier body, may form a robust mechanical base or support and may electrically connect to the top-sided laminated layer stack. The build-up may be a component carrier-type build-up, i.e., constructed as a printed circuit board (PCB) or as an integrated circuit (IC) substrate. In particular, such an additional build-up may refine the electric interconnection of the surface mounted electronic component in particular with the carrier body.

Furthermore, the component carrier may have a bottom-sided layer build-up below the carrier body. Also, on the bottom of the carrier body, an additional layer build-up may be formed, for instance as a laminated layer stack comprising at least one electrically conductive layer structure and/or at least on electrically insulating layer structure. Alternatively, a bottom-sided layer build-up below the carrier body may also be omitted.

In an embodiment, a build-up on one main surface of the carrier body has a higher integration density of electrically conductive structures than another build-up on an opposing other main surface of the carrier body. More specifically, the top-sided layer build-up may have a higher integration density than the bottom-sided layer build-up. The term “integration density” may denote a number of electrically conductive structures per area or volume of the respective region of the component carrier. In particular, the amount of contacts (including pads) per area or volume on the redistribution structure of the top-sided build-up may be higher than the amount of the contacts (including pads) per area or volume on the bottom-sided build-up which may face a mounting base such as a PCB. Thus, integration density may mean a quantity of electrically conductive structures (such as traces) per mm². The integration density below a carrier body can be smaller than in the redistribution structure above the carrier body, and correspondingly the line space ratios may be different. Since PCB and IC substrate technology may be based on larger electrically conductive structures than semiconductor technology (according to which a component connected with the redistribution structure may be formed), the mentioned design rule may be appropriate for bridging the two combined technologies. The side of the component carrier relating to the redistribution structure may provide a mounting area for mounting one or a plurality of electronic components such as semiconductor chips and can thus be provided advantageously with a high integration density. At the same time, the side of the component carrier relating to the bottom-sided layer build-up may be configured for connecting the package at the surface with a mounting base, such as a printed circuit board.

In an embodiment, an extension depth of the conductive interconnection structure into the electrically conductive paste is in a range from 1 μm to 10 μm, in particular in a range from 3 μm to 8 μm. Such an extension depth is sufficiently large, and the shape of the conductive interconnection structure also has enough area in contact with the conductive paste, for ensuring a reliable electric and/or thermal connection between conductive connection structure and the electrically conductive paste. At the same time, such an extension depth is sufficiently small to allow a miniature design of the component carrier. Furthermore, an extension depth in the mentioned ranges may be easily formed by laser drilling into the electrically conductive paste without creating undesired artefacts.

In an embodiment, the at least one hole has an hourglass shape or a continuously tapering shape.

In this context, an hourglass shape may be formed by a through hole having two connected tapering sections with inverse tapering directions (compare FIG. 1). Such an hourglass shape may be obtained by forming the respective hole by laser drilling from both opposing main surfaces of the carrier body.

In alternative embodiments, the respective hole may have a frustoconical shape. Such a continuously tapering shape may be created by laser drilling from only one main surface of the carrier body. The hole may then taper towards the side of the carrier body facing away from the laser source.

Hence, the mentioned hole shapes may be the fingerprint of the respective laser manufacturing process. When the hole is formed by mechanical drilling, it may have straight walls in a cross-sectional view. The hole may then have a circular cylindrical shape.

In an embodiment, the component carrier comprises an electronic component mounted on or above the carrier body and being electrically coupled with the at least one conductive interconnection structure. One or more electronic components may be surface mounted. In the context of the present application, the term “electronic component” may particularly denote a member fulfilling an electronic task. Such an electronic component may be an active component such as a semiconductor chip comprising a semiconductor material, in particular as a primary or basic material. The electronic component may also be a passive component, for instance a capacitor or an inductor. Preferably, the electronic component comprises a semiconductor chip. The semiconductor chip may be made for instance based on a type IV semiconductor such as silicon or germanium or may be a type III-V semiconductor material such as gallium arsenide. In particular, the semiconductor component may be a semiconductor chip such as a bare die or a molded die. A bare die may be a non-encapsulated (in particular non-molded) piece of semiconductor material (such as silicon) having at least one monolithically integrated circuit element (such as a diode or a transistor). Moreover, semiconductor materials suitable for photonic packages are also possible. For example, an electronic component to be surface mounted on the package may be an HBM (high-bandwidth memory) or a silicon interposer.

In an embodiment, the component carrier comprises a plurality of conductive interconnection structures arranged side by side (see, for example, FIG. 1). Each of the conductive interconnection structures may be constructed as described above. Different conductive interconnection structures may be constructed correspondingly, for instance they may all be constructed as metallic via and/or pillars and/or bumps extending into electrically conductive paste. The conductive interconnection structures arranged side-by-side may be manufactured by a common manufacturing process, and hence very efficiently. Multiple conductive interconnection structures extending through the same (preferably glass) carrier body may enable performance of complex electronic tasks by the component carrier.

In an embodiment, traces are arranged between adjacent conductive interconnection structures on or above the carrier body. Such traces may be electrically conductive structures formed as one or more patterned metal layers.

In an embodiment, the traces have a line space ratio in a range from 2 μm/2 μm to 10 μm/10 μm. A trace between the conductive interconnection structures (in particular embodied as metallic vias) may have a line width space in a range from 2 μm/2 μm to 10 μm/10 μm, in particular 5/5 μm. Moreover, a line space ratio of the redistribution structure may be in a range from 2 μm/2 μm to 10 μm/10 μm. Hence, a fine line patterning with very small dimensions is possible on or above the carrier body. This is possible when the carrier body is made of glass, thanks to the extreme smoothness of such a glass body.

In an embodiment, the at least one conductive interconnection structure has a frustoconical shape. Hence, the conductive interconnection structure may taper towards an interior of the carrier body. In another embodiment, the conductive interconnection structure may taper towards an exterior of the carrier body. When using a laser with subsequent plating to form the conductive interconnection structure as metallic via (more precisely as metallic laser via), an obtained shape may correspond to that of a laser via. The laser via may have a shape in which the bottom is very small compared to the top. Hence, the tapering in this situation can be much bigger compared to laser vias in other situations. For example, a tapering angle of a side wall of a conductive interconnection structure embodied as a laser via with respect to a vertical direction may be at least 10°, in particular at least 20°, more particularly at least 30°, for example at least 40°.

In another embodiment, the at least one conductive interconnection structure has a circular cylindrical shape. When using an excimer laser, the via taper can be much smaller, or even zero. When using an exposure, the structure can be straighter, for instance almost or exactly straight.

With a manufacturing method according to an example embodiment of the disclosure, it may be possible to use a PID (photoimageable dielectric) or a dry film or another photoimageable material on the carrier body, in particular when embodied as glass core. The exposure can expose the opening on the conductive paste surface first, and then an etching process may follow to obtain a target extension depth. The metal pillar or bumps can be formed very straight. Additionally, it may be possible to use a plasma to form the vias with small or even zero taper.

In an embodiment, the electrically conductive paste extends up to the same vertical level as the carrier body. In other words, the hole extending into or through the carrier body may be entirely filled with electrically conductive paste. This may simplify the formation of a reliable electrical connection between the electrically conductive paste and the respective conductive interconnection structure. This may lead to a high electric and/or thermal performance of the component carrier. Meanwhile, the configuration of an extension of a respective conductive interconnection structure protruding into the conductive paste provides a good reliability of electrical and thermal connection for the component carrier and/or the whole package. Because bonding or adhesion performance between the two elements significantly impacts the reliability of products.

In an embodiment, the method comprises forming the conductive interconnection structure by laser drilling or etching a recess into the electrically conductive paste, and by subsequently filling the laser drilled or etched recess by a metallic material or another conductive material, in particular by plating, printing, injection, plug-in, etc. The electrically conductive paste in the hole of the carrier body may be processed by a laser beam for drilling a recess into the electrically conductive paste. Thereafter, the recess may be plated with a metal, preferably with copper. Such a plating process may involve, for example, electroless plating, sputtering, galvanic plating, etc. Alternatively, the recess may be filled with another conductive material, for instance with one of the manufacturing technologies mentioned above.

In an embodiment, the method comprises roughening a main surface of the carrier body, and thereafter forming the above-mentioned dielectric layer, on the roughened main surface of the carrier body. Such a process may be executed on one or both opposing main surfaces of the carrier body. Roughening the surface of the carrier body (in particular when made of glass, which may have an extremely smooth surface) may promote adhesion of a subsequently attached dielectric layer. For instance, roughening may be accomplished by etching or grinding.

In an embodiment, the method comprises forming carrier bodies, with at least one hole filled with electrically conductive paste and a conductive interconnection structure extending with direct physical contact into the metallic paste on each of two opposing main surfaces of a dummy carrier. Thereafter, it may be possible to separate each carrier body with at least one hole filled with metallic paste and conductive interconnection structure extending with direct physical contact into the metallic paste from both opposing main surfaces of the dummy carrier. A corresponding process is shown in FIG. 12 to FIG. 16. Such a manufacturing architecture may enable the formation of respective component carriers on both opposing main surfaces of the dummy carrier. This may lead to a high yield and a very efficient manufacturing process which allows manufacturing component carriers on a high industrial scale.

In an embodiment, the method comprises filling the at least one hole with the electrically conductive paste, and thereafter removing, in particular by grinding, excessive electrically conductive paste outside of the at least one hole. It may be difficult to exactly fill the one or more holes in the carrier body with electrically conductive paste such that it is flush with the respective main surface of the carrier body. On the other hand, a proper connection of the conductive interconnection structure with electrically conductive paste may be significantly simplified when the electrically conductive paste extends up to the mentioned main surface of the carrier body. In order to ensure this, it is possible so fill the hole of the carrier body with slightly excessive electrically conductive paste to ensure complete filling and thereafter removing excessive paste material by grinding. This may enable the production of a component carrier with high reliability.

In an embodiment, the component carrier comprises a mounting base, in particular a printed circuit board (PCB), on which the component carrier is mounted. Such a mounting base may connect the component carrier and its surface mounted component(s) mechanically and electrically with an electronic periphery.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier is shaped as a plate. This contributes to the compact design, wherein the component carrier nevertheless provides a large basis for mounting components thereon. In particular a naked die as an example for an electronic component can be surface mounted on a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). A printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, Melamine derivates, Polybenzoxabenzole (PBO), bismaleimide-triazine resin, polyphenylene derivate (e.g. based on polyphenylenether, PPE), polyimide (PI), polyamide (PA), liquid crystal polymer (LCP), polytetrafluoroethylene (PTFE), Bisbenzocyclobutene (BCB) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten and magnesium. Although copper is usually preferred, other materials or coated versions thereof are possible as well, in particular materials coated with supra-conductive material or conductive polymers, such as graphene or poly(3,4-ethylenedioxythiophene) (PEDOT), respectively.

The at least one component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SIC), gallium arsenide (GaAs), gallium nitride (GaN), gallium oxide (Ga₂O₃), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be surface mounted on the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

The embodiments defined above and further embodiments consistent with the disclosure are apparent from the examples of embodiment to be described hereinafter and are explained with reference to these examples of embodiment.

### BRIEF DESCRIPTION OF THE DRAWINGS

FIG. 1 illustrates a cross-sectional view of a component carrier according to an example embodiment of the disclosure.

FIG. 2, FIG. 3, FIG. 4, FIG. 5, FIG. 6, and FIG. 7 illustrate cross-sectional views of structures obtained during carrying out a method of manufacturing a component carrier, shown in FIG. 7, according to another embodiment of the disclosure.

FIG. 8, FIG. 9, FIG. 10, and FIG. 11 illustrate cross-sectional views of structures obtained during carrying out methods of manufacturing a component carrier according to an embodiment of the disclosure.

FIG. 12, FIG. 13, FIG. 14, and FIG. 15 illustrate cross-sectional views of structures obtained during carrying out a method of manufacturing a component carrier according to another embodiment of the disclosure.

FIG. 16 illustrates a cross-sectional view of a component carrier according to an example embodiment of the disclosure.

### DETAILED DESCRIPTION OF THE ILLUSTRATED EMBODIMENTS

The illustrations in the drawings are schematically presented. In different drawings, similar or identical elements are provided with the same reference signs.

Before, referring to the drawings, example embodiments will be described in further detail, some basic considerations will be summarized based on which embodiments of the disclosure have been developed.

Fan-out wafer level packaging (FOWLP) is an advantageous technology for package miniaturization concerning package volume and thickness, which enables a greater number of input/output (I/O) connections. FOWLP may involve the formation of a reconfigured molded wafer combined with a thin-film redistribution layer to yield an SMD-compatible package. In this way, a substrate-less package with low thermal resistance and excellent high-frequency performance may be provided. Proper radio-frequency performance may be achieved due to shorter interconnects together with a direct integrated circuit connection by thin-film metallization instead of wire bonds or flip chip bumps and lower parasitic effects. FOWLP can be used for multi-chip packages, for System in Package (SiP) applications and for heterogeneous integration. For even higher productivity and resulting lower cost, larger mold embedding form factors may be implemented.

Besides increasing wafer diameter, another option is moving to panel sizes leading to fan-out panel level packaging (FOPLP) which provides more efficiency for high volume manufacturing compared to FOWLP.

According to an embodiment of the disclosure, a component carrier (which may be used for mounting one or more electronic components, such as semiconductor chips, thereon) is provided which is manufacturable in a simple and reliable way. For this purpose, a carrier body may be provided with one or more holes. Electrically conductive paste, such as metallic paste, may be filled in the one or more holes. Advantageously, one or more (preferably thermally and/or electrically) conductive interconnection structures may be formed or inserted in another way into the electrically conductive paste. Consequently, the (for instance tapering or spike-shaped) conductive interconnection structure(s) may protrude into the electrically conductive paste. In a simple way, this enables a direct physical contact between an interconnection structure and the electrically conductive paste, and hence a reliable electric and/or thermal coupling in between.

Briefly, a component carrier according to an embodiment of the disclosure may provide a very stable chip packaging substrate with asymmetric glass core and conductive paste filled in a through glass via (TGV). Furthermore, fine structuring may be executed on or above the carrier body made of glass. Moreover, a high-density build-up layer may be formed on top to connect with chips in a chip last FOPLP architecture. In particular, a component carrier may be provided which may be configured as fan-out substrate with an asymmetric glass core.

More specifically, an embodiment of the disclosure provides a component carrier with fan-out functionality. A component carrier may be an asymmetric glass core which may be used as carrier body. Such a glass core may be provided with holes in the form of laser drilled through glass vias (TGVs) which may be filled with a conductive paste. A respective conductive interconnection structure, preferably a metallic via, may be formed or inserted into the conductive paste for establishing a thermal and/or electrically conductive connection between conductive interconnection structure and paste.

A component carrier according to an embodiment of the disclosure may be manufactured based on an asymmetric glass core with subsequent fine structuring. This may improve the warpage behavior of the component carrier. A high chip packaging performance and yield may be obtained in view of a chip last manufacturing architecture by which one or more electronic components may be surface mounted on the component carrier at the very end of the manufacturing process. Furthermore, an improved adhesion between glass and a dielectric material formed on the glass may be obtained by previously grinding or etching the glass surface. Advantageously, a very fine pitch with land-less design (by grinding to obtain a fine hole) may be formed on the glass carrier body. Beneficially, an improved warpage management may be achieved during processing when implementing an asymmetric glass core. The described component carrier may experience a good signal integrity for high-speed signals with shorter path length. In view of advantageous glass properties (in particular a low Df value), high signal quality may be obtained, in particular for high-frequency operations. Furthermore, better packaging conditions may be achieved with higher stiffness by a thicker glass core, in comparison with conventional approaches. A high yield may be achieved by a manufacturing process implementing fan-out panel level packaging, as stiffness of the glass can mitigate the dimensional change (such as warpage, shrinkage) with good alignment and coplanarity for the whole product.

Example applications of embodiments of the disclosure relate to component carriers for mobile phones, servers, computing applications, in particular high-performance computing (HPC), and related electronic devices.

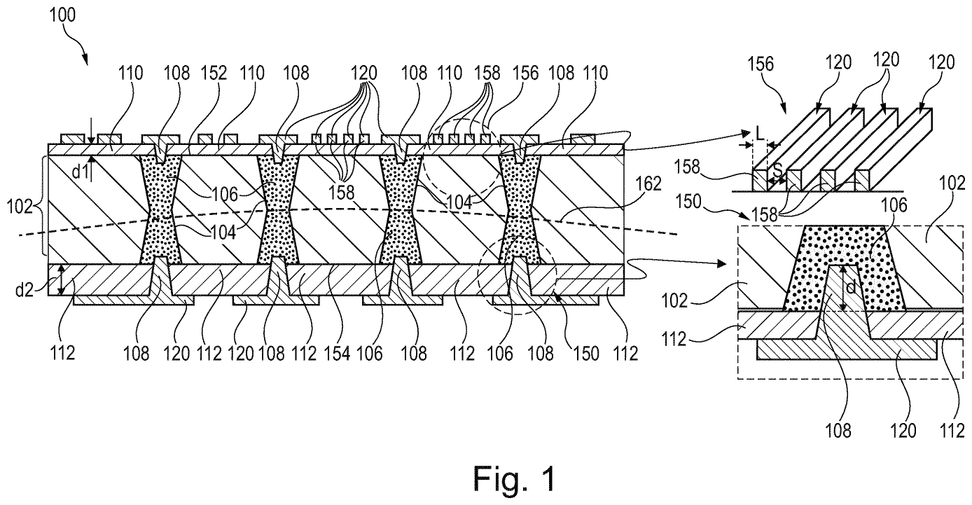

FIG. 1 illustrates a cross-sectional view of a component carrier 100 according to an embodiment of the disclosure.

The illustrated component carrier 100 comprises a central carrier body 102 having a plurality of vertically extending through holes 104 extending through the entire carrier body 102. The carrier body 102 may be embodied as glass plate. The through holes 104 extending side-by-side vertically through the carrier body 102 may then be through glass vias (TGVs). They may be formed in the carrier body 102 by laser drilling from opposing main surfaces 152, 154 of the carrier body 102. As a result, the through holes 104 have an hourglass shape composed of two connected tapering sections with opposite tapering directions.

Again referring to FIG. 1, electrically conductive paste 106 is filled in each of said holes 104. For example, the electrically conductive paste 106 may comprise copper particles. As illustrated, the electrically conductive paste 106 may extend up to each of the opposing main surfaces 152, 154 of the carrier body 102. Hence, the electrically conductive paste 106 extends up to the same vertical levels as the carrier body 102, both at a bottom side and at a top side.

Two opposing conductive interconnection structures 108 may be provided per through hole 104, each extending with direct physical contact into said electrically conductive paste 106. More specifically, each hole 104 with filling of electrically conductive paste 106 has an upper end section connected by an upper conductive interconnection structure 108 and has an opposing lower end section connected by a lower conductive interconnection structure 108. The tapering directions of the upper conductive interconnection structure 108 and of the lower conductive interconnection structure 108 may be inverse to each other, so that both may taper towards an interior of the carrier body 102. In the illustrated embodiment, the conductive interconnection structures 108 consist of solid copper and are thus both electrically conductive and thermally conductive. In the embodiment of FIG. 1, each conductive interconnection structure 108 has a frustoconical shape or a cylindrical shape and is embodied as tapering metallic via which tapers towards an interior of the carrier body 102. Such a tapering via may be formed by laser drilling followed by copper plating. Although not shown, an alternative embodiment may have a conductive interconnection structure 108 tapering towards an exterior of the carrier body 102. As shown in a detail 150 in FIG. 1, an extension depth, d, of a respective conductive interconnection structure 108 into the electrically conductive paste 106 may be preferably 3 μm to 8 μm. This may ensure a sufficiently large connection area between electrically conductive paste 106 and conductive interconnection structure 108 and may also be compatible with the laser process used for drilling a recess in the electrically conductive paste 106.

As shown as well in FIG. 1, a dielectric layer 110 is arranged directly on an upper main surface 152 of the carrier body 102. A thickness, d1, of the dielectric layer 110 may be for example 10 μm. Dielectric layer 110 may for instance be a resin layer, a prepreg layer or a layer made of a photoimageable dielectric. As shown, all upper conductive interconnection structures 108 extend entirely through the dielectric layer 110 into the respective electrically conductive paste 106.

Correspondingly, a further dielectric layer 112 is arranged directly on a lower main surface 154 of the carrier body 102. A thickness, d2, of the further dielectric layer 112 may be for example 100 μm. Hence, the further dielectric layer 112 may be thicker than the dielectric layer 110. Further dielectric layer 112 may for instance be a resin layer, a prepreg layer or a layer made of a photoimageable dielectric. As shown, all lower conductive interconnection structures 108 extend entirely through the further dielectric layer 112 into the respective electrically conductive paste 106.

By the different thicknesses, d1 and d2, of the dielectric layers 110, 112, different thicknesses of an asymmetric build-up on both sides of the carrier body 102 may be compensated. Such an asymmetric build-up is not shown in FIG. 1, but for instance in FIG. 7 (see reference signs 116, 118). Briefly, the thicknesses d1 and d2 may be used as design parameters for at least partially compensating for an asymmetric build-up to thereby reduce warpage of component carrier 100 and thus improve its reliability and product yield. A further advantage of forming the dielectric layers 110, 112 on the respective main surface 152, 154 of the carrier body 102 is that this may improve adhesion of the below described electrically conductive structures 120 (which may be made of copper) on both sides. The extremely smooth glass surface of the carrier body 102, for instance having a roughness of less than 50 nm, has the advantage of enabling the creation of a fine line pattern (see detail 156 in FIG. 1) by the electrically conductive structures 120 with very small pitch or line space ratio. However, direct formation of copper material of the electrically conductive structures 120 on the glass carrier body 102 may be challenging in terms of adhesion. Advantageously, adhesion of a dielectric layer 110, 112 on the glass surface of the carrier body 102 is however possible. When the electrically conductive structures 120 are formed directly on the thin dielectric layer 110, they may still profit from the pronounced smoothness of the glass surface of the carrier body 102 but may adhere in a much more reliable way.

Electrically conductive structures 120 may be formed on the exposed surfaces of the respective dielectric layer 110, 112. For instance, a metal layer may be formed (for instance by plating, in particular copper plating) or attaching (for example as metal foil, in particular copper foil) on the respectively exterior side of the respective dielectric layer 110, 112. Thereafter, the metal layer may be patterned, for instance by a lithography and etching process to thereby obtain the electrically conductive structures 120 according to FIG. 1. As already mentioned, the component carrier 100 comprises a plurality of conductive interconnection structures 108 arranged laterally side by side and vertically facing each other. Fine line traces 158 of the electrically conductive structures 120 are arranged between adjacent conductive interconnection structures 108 on dielectric layer 110 and closely above the carrier body 102. With the described manufacturing architecture, the fine line traces 158 may be formed with a very small line space ratio L/S in a range from 2 μm/2 μm to 10 μm/10 μm. Referring to detail 156, a line width, L, may form the first dimension of the L/S ratio, whereas a space between adjacent lines, S, may form the second dimension of the L/S ratio.

Still referring to FIG. 1, the dimensions of the electrically conductive structure 120 on the exterior surface of the further dielectric layer 112 may be much coarser than on the exterior surface of the dielectric layer 110. In other words, the integration density, i.e. the number of electrically conductive elements of the electrically conductive structure 120 per area or volume, may be larger above the dielectric layer 110 than below the further dielectric layer 112.

As already mentioned, the build-ups on the top side and on the bottom side of the carrier body 102 may be asymmetric. A reason for this asymmetry is that the top side is configured to comply with requirements of semiconductor chip technology, since electronic components 122 are to be mounted on the top side (see FIG. 7). On the other hand, the bottom side shall comply with requirements of PCB technology or the like, since the bottom side of the component carrier 100 may have to be mounted on a mounting base 160 such as a PCB (see FIG. 7). However, the pronounced rigidity of the glass carrier body 102 may lead to an acceptable degree of warpage 162 despite of the asymmetry. By forming appropriately designed build-ups 116, 118, warpage 162 may be further reduced (see FIG. 9), and product manufacturing effort and cost may be saved.

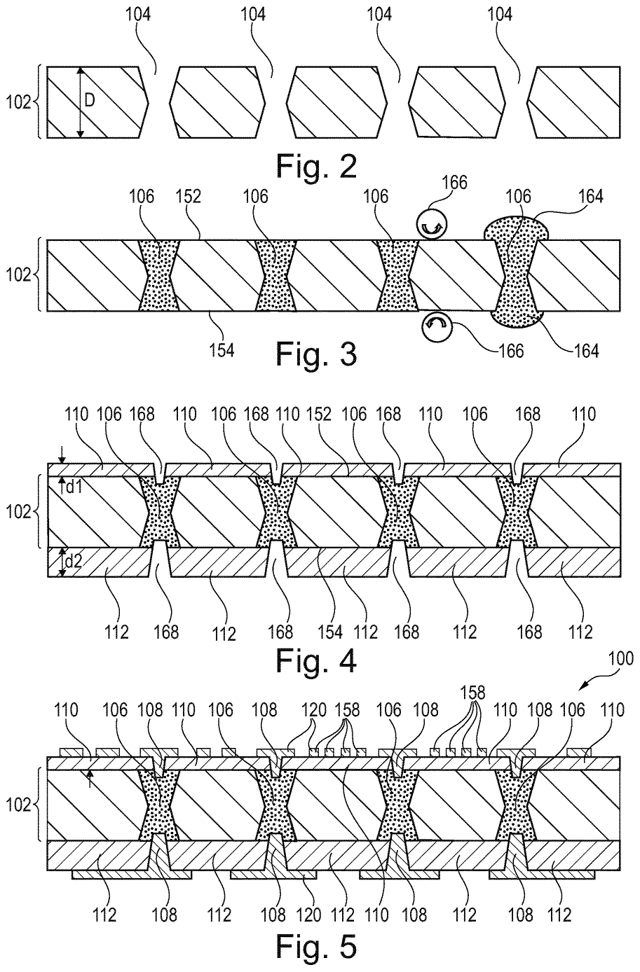

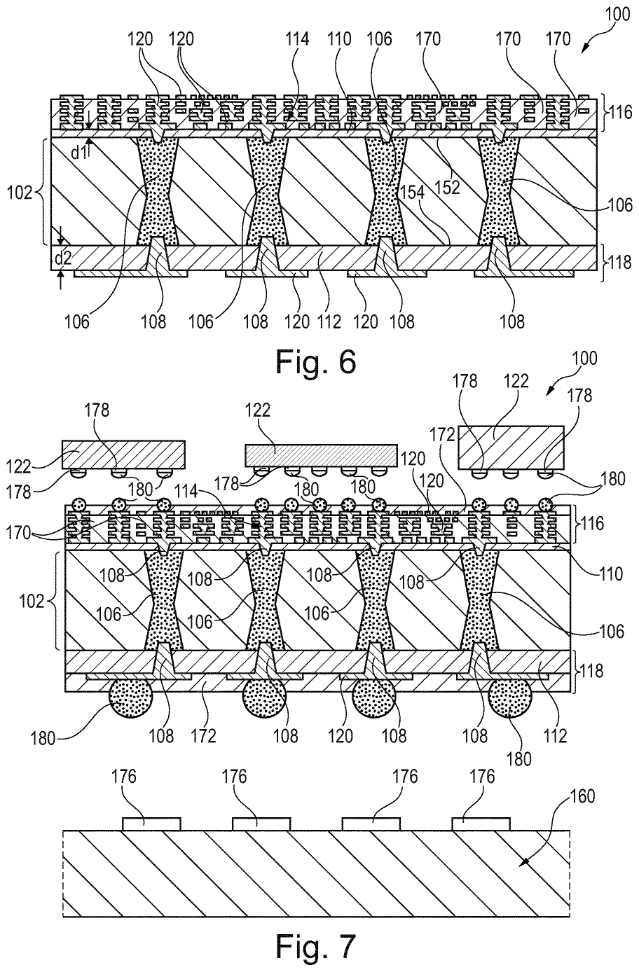

FIG. 2 to FIG. 7 illustrate cross-sectional views of structures obtained during carrying out a method of manufacturing a component carrier 100, shown in FIG. 7, according to another embodiment of the disclosure.

Referring to FIG. 2, a carrier body 102 may be provided as a glass plate. For example, the glass carrier body 102 has a thickness, D, in a range from 30 μm to 2000 μm, for example in a range from 500 μm to 1500 μm. A sufficiently high thickness, D, may allow to provide a sufficient robustness and rigidity for efficiently suppressing warpage. A plurality of through holes 104 may be formed in the carrier body 102 by laser drilling. For this purpose, a laser source (not shown) may drill a first tapering laser hole in an upper portion of the carrier body 102 and may drill a second tapering laser hole in a lower portion of the carrier body 102 which may connect to form an hourglass-shaped through hole 104, as shown. Hence, the through holes 104 may be through glass vias (TGVs).

Referring to FIG. 3, electrically conductive paste 106 is inserted into each through hole 104. For example, this can be accomplished by an appropriate medium applicator (not shown). In the context of the present application, the term “medium applicator” may particularly denote a movable device configured for applying electrically conductive paste 106 into a respective hole 104, in particular in a metered or dosed way. For instance, a medium applicator may comprise a printer or printhead configured for applying the electrically conductive paste 106 into the respective hole 104 by printing, for instance by injection printing. However, the medium applicator may also be a dispenser or the like.

After having filled the holes 104, it may happen that excessive electrically conductive paste 106 protrudes beyond a respective hole 104, see reference sign 164. By grinding using a grinding tool 166, excessive electrically conductive paste 106 outside of the hole 104 may be removed until the electrically conductive paste 106 is in flush with exterior main surfaces 152, 154 of the carrier body 102. For instance, the electrically conductive paste 106 may be of sintering type.

Referring to FIG. 4, the main surfaces 152, 154 of the carrier body 102 may be roughened. This may improve the adhesion of dielectric layers 110, 112 which are subsequently attached asymmetrically onto the roughened main surfaces 152, 154 of the carrier body 102. As described above referring to FIG. 1, the thickness d2 of the further dielectric layer 112 may be larger than the thickness d1 of the dielectric layer 110. Each of dielectric layers 110, 112 may be a dielectric laminate. Dielectric layers 110, 112 may be connected with the carrier body 102 by lamination, i.e. the application of heat and/or pressure.

Thereafter, both opposing main surfaces of the obtained structure may be subjected to laser drilling for exposing the electrically conductive paste 106 by access holes 168 each extending through the entire respective dielectric layer 110, 112 and into the electrically conductive paste 106.

Referring to FIG. 5, electrically conductive material (preferably copper) may be applied into the access holes 168 and onto the exposed surface of dielectric layers 110, 112. For instance, this may be done by plating. For example, such a plating process may include electroless plating followed by galvanic plating.

The metallic filling of the access holes 168 forms electrically and thermally conductive interconnection structures 108, preferably of copper. As a result, the formed conductive interconnection structures 108 extend with direct physical contact into the assigned electrically conductive paste 106. As shown in FIG. 4 and FIG. 5, the conductive interconnection structure 108 is formed by laser drilling a respective recess (corresponding to a respective access hole 168) into the electrically conductive paste 106, followed by subsequently filling the laser drilled recess by plated copper (or another metal).

After plating, the obtained metal layer on the dielectric layers 110, 112 may be patterned, for instance by a lithography and etching process, for forming the patterned electrically conductive structures 120. On the dielectric layer 110, the obtained patterned electrically conductive structure 120 includes the fine line traces 158 with a very small line space ratio L/S of for example 5 μm/5 μm. On the further dielectric layer 112, the obtained patterned electrically conductive structure 120 is coarser.

The obtained component carrier 100 may be used as such or may be further processed as asymmetric core on which a further build-up may be formed.

Referring to FIG. 6, a top-sided build-up 116 (which may be embodied as a layer stack) may be formed on the dielectric layer 110 and on the electrically conductive structure 120 thereon and therein. Correspondingly, a bottom-sided further build-up 118 (which may be embodied as a layer stack) may be formed.

Hence, the build-ups 116, 118 above the two opposing main surfaces 152, 154 of the carrier body 102 are asymmetric. This asymmetry is due to the different functions of the build-ups 116, 118, as described in the following. However, in order to keep warpage due to this functionally caused asymmetry small, the higher thickness of the build-up 116 in comparison with the smaller thickness of the further build-up 118 may be compensated partially or entirely by the different thicknesses d1, d2 of the dielectric layers 110, 112.

As shown, a redistribution structure 114 is formed as part of the build-up 116 and above the upper main surface 152 of the carrier body 102. No redistribution structure is formed as part of the further build-up 118. The top-sided conductive interconnection structures 108 pass through or form part of the redistribution structure 114. Also, the dielectric layer 110 may form part of the redistribution structure 114.

As a result of the described construction, the build-ups 116, 118 on two opposing main surfaces 152, 154 of the carrier body 102 are asymmetric. In particular, the build-up 116 on the upper main surface 152 of the carrier body 102 has a higher integration density of electrically conductive structures 120 than the other build-up 118 on the lower main surface 154 of the carrier body 102.

The build-up 116 may comprise or consist of a laminated layer stack comprising a plurality of electrically conductive layer structures forming the electrically conductive structures 120 and comprising electrically insulating layer structures 170. The electrically conductive layer structures may comprise patterned copper layers which may form horizontal pads and/or a horizontal wiring structure. Additionally or alternatively, the electrically conductive layer structures may comprise vertical through connections such as copper pillars and/or copper filled laser vias. Moreover, the stack of the component carrier 100 may comprise one or more electrically insulating layer structures 170 (such as prepreg or resin sheets).

Referring to FIG. 7, a plurality of electronic components 122 are surface mounted on the build-up 116 above the carrier body 102 and are electrically coupled with the conductive interconnection structures 108 by the electrically conductive structures 120.

One or more electronic components 122 may be surface mounted on the component carrier 100. In particular, the illustrated electronic component(s) 122 may be a semiconductor chip, for example for data computing, as a memory, for power management of RF (radio frequency) applications.

Electrically conductive pads 178 of the electronic components 122 may be electrically connected with the electrically conductive structures 120 of build-up 116 by bonding structures 180, such as solder balls.

Also, surface finish 172 (like ENIG or ENEPIG, a solder resist, etc.) may be optionally applied on the top side of build-up 116 and/or on the bottom side of the build-up 118. The exterior electrically insulating layer structures are formed as a surface finish 172 embodied as solder resist. The solder resist may support correct soldering of component carrier 100 on electrically conductive pads 176 of a mounting base 160 below (for example a printed circuit board) by bonding structures 180, such as solder balls. Correspondingly, the solder resist may support correct soldering of electronic components 122 on build-up 116 by bonding structures 180.

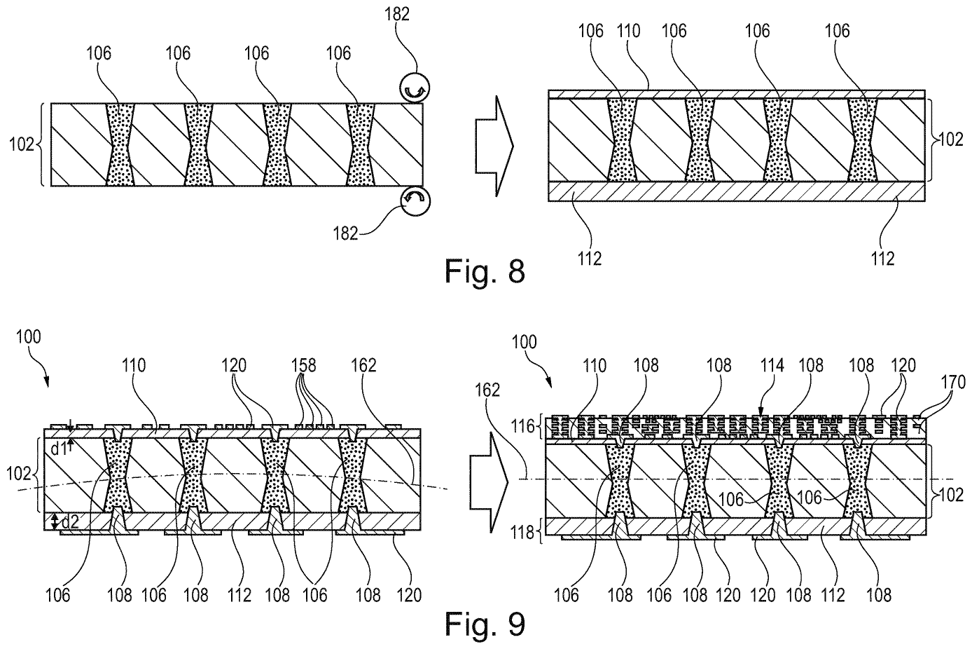

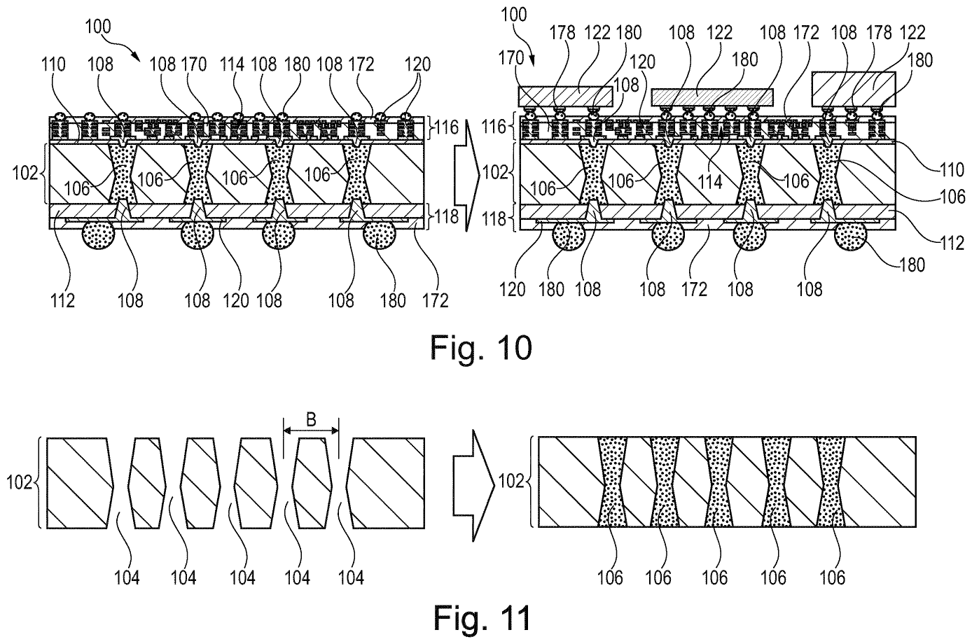

FIG. 8 to FIG. 11 illustrate cross-sectional views of structures obtained during carrying out methods of manufacturing a component carrier 100 according to embodiments of the disclosure.

FIG. 8 shows that a better adhesion between glass of the carrier body 102 and a respective one of the dielectric layers 110, 112 may be achieved by grinding the glass surface by grinding or etching tools 182 prior to attaching the dielectric layers 110, 112.

FIG. 9 illustrates that a better warpage management can be achieved during the manufacturing process by forming the asymmetric glass core according to FIG. 5. Due to the different thicknesses d1, d2 of the dielectric layers 110, 112, the asymmetric glass core shown on the left-hand side of FIG. 9 still experiences some warpage 162. However, by forming the build-up(s) 116, 118 on the dielectric layer 110, 112 with inverse asymmetry, a partial or entire compensation of the asymmetry may be achieved leading to a further reduced warpage 162 shown on the right-hand side of FIG. 9. Briefly, a larger thickness d2 of the further dielectric layer 112 compared with a smaller thickness d1 of the dielectric layer 110 may at least partially compensate for a larger thickness of the build-up 116 compared with a smaller thickness of the build-up 118.

The illustrated asymmetric glass core with fine structuring already comprises interconnecting vias (more generally conductive interconnection structures 108) protruding or penetrating into electrically conductive paste 106 for improved reliability.

Referring to FIG. 10, the illustrated manufacturing method ensures a good signal integrity for high-speed signals in view of the enabled short path length and the low Df and/or Dk value of the glass material of the carrier body 102. Furthermore, robust packaging conditions with high stiffness may be achieved by the use of a thick glass core. As a result, a FOPLP-type component carrier 100 with high yield may be manufactured. The yield may be further enhanced by the illustrated chip last packaging process.

Referring to FIG. 11, a pitch, B, between adjacent holes 104 in carrier body 102 may be reasonably small, for instance in a range from 20 μm to 200 μm, preferably not more than 100 μm.

As a result, the manufacturing process may be executed with low effort. Formation of through glass vias (TGVs) in the glass plate of the carrier body 102 may be sufficient, and no patterning on glass is necessary. This may enable a fine pitch with a landless characteristic on glass. Filling or plugging of holes 104 with sintering electrically conductive paste 106 may be accomplished by a vacuum printer, etc.

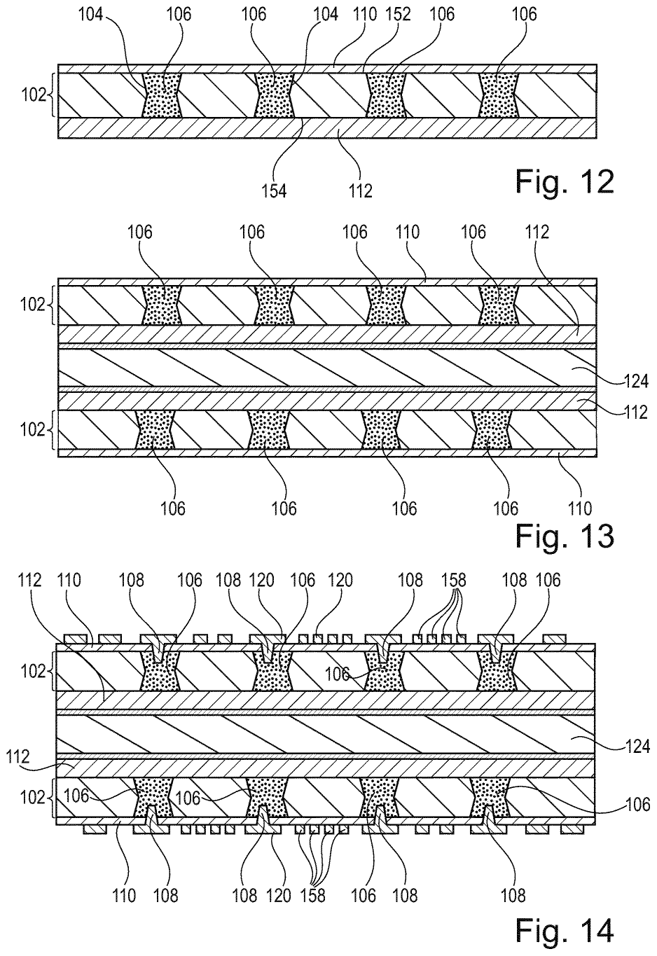

FIG. 12 to FIG. 15 illustrate cross-sectional views of structures obtained while carrying out a method of manufacturing a component carrier 100 according to another embodiment of the disclosure.

Referring to FIG. 12, a starting point of the method is a structure which can be obtained by attaching dielectric layers 110, 112 to both opposing main surfaces 152, 154 of the carrier body 102 of the structure shown in FIG. 3. Consequently, a carrier body 102 with through holes 104 filled with electrically conductive paste 106 and attached dielectric layers 110, 112 is obtained.

Referring to FIG. 13, two structures according to FIG. 12 are mounted on a dummy carrier 124. More specifically, one structure according to FIG. 12 may be attached to each of two opposing main surfaces of the dummy carrier 124. For instance, dummy carrier 124 may be a DCF carrier. The connection of the structures of FIG. 12 to the dummy carrier 124 may be accomplished by soft lamination of the respective dielectric layer 112 on dummy carrier 124.

Referring to FIG. 14, respective conductive interconnection structures 108 extending with direct physical contact into the metallic paste 106 may be formed in the exposed surfaces of the structures attached on each of two opposing main surfaces of the dummy carrier 124. This process can be carried out as described above referring to FIG. 4 and FIG. 5, however only on the side with the fine line structures 158.

Referring to FIG. 15, a respective build-up 116 with redistribution structure 114 is formed on the exposed sides with the fine line structures 158. This process can be carried out as described above referring to FIG. 6.

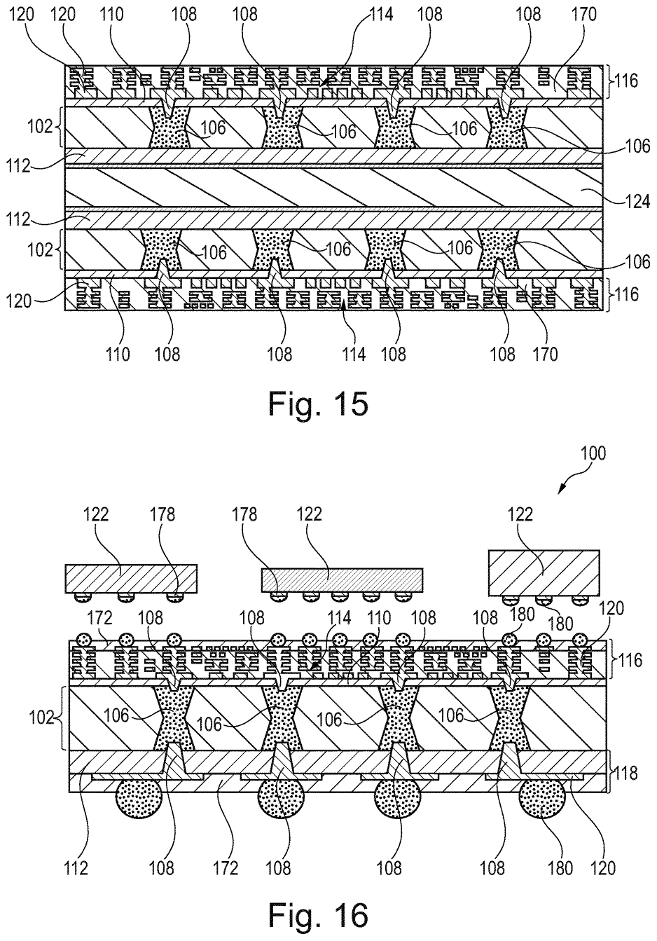

FIG. 16 illustrates a cross-sectional view of a component carrier 100 according to an embodiment of the disclosure.

In order to obtain the component carrier 100 based on the structure shown in FIG. 15, each carrier body 102 with holes 104 filled with metallic paste 106 and conductive interconnection structure 108 extending with direct physical contact into the metallic paste 106 may be detached from both opposing main surfaces of the dummy carrier 124.

Thereafter, the side of the obtained structures corresponding to the further dielectric layer 112 which has previously been connected to the dummy carrier 124 may be further processed. This further processing may involve forming the conductive interconnection structures 108 extending through further dielectric layer 112 and forming the further build-up 118. This can be done as described above referring to FIG. 4 and FIG. 5.

Furthermore, obtained component carriers 100 may be subjected to the processes which form surface finish 172 and bonding structures 180. Moreover, the components 122 may be surface mounted.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principles according to the disclosure even in the case of fundamentally different embodiments.

1. A component carrier, comprising:
a carrier body having at least one hole;
electrically conductive paste in at least part of the at least one hole; and
at least one conductive interconnection structure extending with direct physical contact into the electrically conductive paste.

2. The component carrier according to claim 1, wherein the at least one hole is at least one through-hole extending through the entire carrier body.

3. The component carrier according to claim 1, wherein the carrier body is an inorganic carrier body comprising glass, ceramic, or a semiconductor.

4. The component carrier according to claim 1, wherein the carrier body is an organic carrier body comprising a resin.

5. The component carrier according to claim 1, wherein at least two conductive interconnection structures are provided, each one extending with direct physical contact into the electrically conductive paste from a respective one of two opposing ends of the at least one hole extending through the entire carrier body.

6. The component carrier according to claim 1, comprising a dielectric layer directly on a main surface of the carrier body, wherein the conductive interconnection structure extends through the dielectric layer,
a further dielectric layer directly on an opposing other main surface of the carrier body, wherein a further conductive interconnection structure extends through the further dielectric layer into the electrically conductive paste,
wherein the dielectric layer has a smaller thickness than a thickness of the further dielectric layer.

7.-8. (canceled)

9. The component carrier according to claim 1, comprising a redistribution structure formed on or above a main surface of the carrier body formed only on or above one of two opposing main surfaces of the carrier body and/or wherein the at least one conductive interconnection structure passes through at least part of the redistribution structure.

10. The component carrier according to claim 6, wherein the redistribution structure is formed on the dielectric layer or is formed so that the dielectric layer forms part of the redistribution structure.

11. The component carrier according to claim 1, wherein a build-up on two opposing main surfaces of the carrier body is asymmetric.

12. The component carrier according to claim 1, wherein a build-up on one main surface of the carrier body has a higher integration density of electrically conductive structures than another build-up on an opposing other main surface of the carrier body.

13. The component carrier according to claim 1, wherein an extension depth of the conductive interconnection structure into the electrically conductive paste is in a range from 1 μm to 10 μm.

14. The component carrier according to claim 6, wherein a thickness of the dielectric layer is in a range from 5 μm to 20 μm.

15. The component carrier according to claim 6, wherein a thickness of the further dielectric layer is in a range from 50 μm to 200 μm.

16. The component carrier according to claim 1, wherein the at least one hole has an hourglass shape or a continuously tapering shape.

17. The component carrier according to claim 1, comprising an electronic component mounted on or above the carrier body and being electrically coupled with the at least one conductive interconnection structure.

18. The component carrier according to claim 1, comprising a plurality of conductive interconnection structures arranged side by side, wherein traces are arranged between adjacent conductive interconnection structures on or above the carrier body,
wherein the traces have a line space ratio in a range from 2 μm/2 μm to 10 μm/10 μm.

19. (canceled)

20. The component carrier according to claim 1, wherein the at least one conductive interconnection structure has a frustoconical shape.

21. The component carrier according to claim 1, wherein the electrically conductive paste extends up to the same vertical level as the carrier body.

22. A method of manufacturing a component carrier, comprising:
providing a carrier body with at least one hole;
inserting electrically conductive paste into at least part of the at least one hole; and
forming at least one conductive interconnection structure extending with direct physical contact into the electrically conductive paste.

23. The method according to claim 19, further comprising at least one of the following features:
wherein the method comprises forming the conductive interconnection structure by laser drilling a recess into the electrically conductive paste, and by subsequently filling the laser drilled recess by a metallic material by plating;
wherein the method comprises roughening a main surface of the carrier body, and thereafter forming a dielectric layer on the roughened main surface of the carrier body;
wherein the method comprises forming carrier bodies with at least one hole filled with electrically conductive paste and a conductive interconnection structure extending with direct physical contact into the electrically conductive-paste on each of two opposing main surfaces of a dummy carrier, and thereafter separating each carrier body with at least one hole filled with electrically conductive paste and conductive interconnection structure extending with direct physical contact into the electrically conductive paste from both opposing main surfaces of the dummy carrier;
wherein the method comprises filling the at least one hole with the electrically conductive paste and thereafter removing by grinding excessive electrically conductive paste outside of the at least one hole.

24.-26. (canceled)
